(19) United States
(12) Patent Application Publication
(10) Pub. No.: US 2025/0375899 A1
(43) Pub. Date: Dec. 11, 2025

(54) SUBSTRATE TRANSFER APPARATUS AND SUBSTRATE PROCESSING APPARATUS INCLUDING SUBSTRATE TRANSFER APPARATUS

(71) Applicant: SCREEN Holdings Co., Ltd., Kyoto (JP)

(72) Inventor: Takashi SHINOHARA, Kyoto (JP)

(73) Assignee: SCREEN Holdings Co., Ltd., Kyoto (JP)

(21) Appl. No.: 19/232,811

(22) Filed: Jun. 9, 2025

(30) Foreign Application Priority Data
Jun. 11, 2024 (JP) 2024-094268

(51) Int. Cl. B25J 15/00; B25J 11/00

(52) U.S. Cl. CPC B25J 15/0014; B25J 11/0095; B25J 15/0028

(57) ABSTRACT

A first hand includes a first pusher for gripping a substrate, the first pusher being provided at a proximal end of a branched blade and at a position sandwiched between a pair of first proximal end guides. A second hand includes a second pusher for gripping a substrate, the second pusher being provided at a position sandwiched between a pair of second proximal end guides. The first pusher includes a first member and a second member, against each of which the substrate comes into abutment, and the second pusher is provided at a position sandwiched between the first member and the second member.

### CROSS-REFERENCE TO RELATED APPLICATION

This application claims priority to Japanese Patent Application No. 2024-094268 filed Jun. 11, 2024, the subject matter of which is incorporated herein by reference in entirety.

### BACKGROUND

### Technical Field

The invention relates to a substrate transfer apparatus capable of transferring multiple horizontally oriented substrates simultaneously, and a substrate processing apparatus including the substrate transfer apparatus.

### Description of Related Art

Patent Document 1 describes a robot for transferring substrates. The robot includes multiple blades capable of holding substrates oriented horizontally. The blades are vertically aligned and capable of receiving horizontally oriented substrates that are vertically aligned with spacing therebetween, simultaneously. Each of the blades has, on the proximal part thereof, a movable abutting portion for gripping a substrate (hereinafter, referred to as a “pusher”). The pushers are vertically stacked and aligned.

However, the configuration described above, there may be cases where the substrates cannot be gripped reliably. In recent years, the substrates to be transferred by a substrate transfer apparatus have become diversified. Therefore, there is a demand for a substrate transfer apparatus also capable of transferring warped substrates or thick substrates formed of multiple substrates that are bonded to each other. Current pushers may fail to grip the substrates reliably because such pushers do not have enough thickness in the vertical direction. Because the pushers are vertically stacked on top of each other, there is a limitation in the degree by which the pusher can be thickened in the vertical direction.

The invention has been made in view of such a circumstance, and an object of the invention is to provide a substrate transfer apparatus capable of gripping a substrate reliably, and a substrate processing apparatus including the substrate transfer apparatus.

### SUMMARY

An aspect of the invention provides a substrate transfer apparatus transferring a substrate. The substrate transferring apparatus includes: a first hand, able to grip a substrate in a horizontal orientation; a second hand, able to grip a substrate, different from the substrate, in a horizontal orientation; a holder, aligning the first hand and the second hand in a vertical direction and holding the first hand and the second hand; an arm, movably supporting the holder; and a base member, supporting the arm.

The first hand includes: a first blade; a pair of first proximal end guides, provided at a proximal end of the first blade and supporting the substrate by coming into contact with a bottom surface of the substrate; a pair of first distal end guides, provided at a distal end of the first blade and supporting the substrate by coming into contact with the bottom surface of the substrate; and a first pusher, provided for gripping the substrate, disposed at the proximal end of the first blade, and at a position sandwiched between the pair of first proximal end guides.

The second hand includes: a second blade; a pair of second proximal end guides, provided at a proximal end of the second blade and supporting the substrate by coming into contact with a bottom surface of the substrate; a pair of second distal end guides, provided at a distal end of the second blade and supporting the substrate by coming into contact with the bottom surface of the substrate; and a second pusher, provided for gripping the substrate, disposed at the proximal end of the second blade, at a position sandwiched between the pair of second proximal end guides. The first pusher includes a first member and a second member, each of the first member and the second member pressing the substrate forward by coming into abutment against the substrate, the second pusher includes a third member that presses the substrate forward by coming into abutment against the substrate, and the third member is at a position sandwiched between the first member and the second member in a plan view.

In addition, another aspect of the invention provides a substrate processing apparatus including the substrate transfer apparatus. The substrate processing apparatus includes a single wafer processing chamber that performs a predetermined process on the substrate.

### BRIEF DESCRIPTION OF THE DRAWINGS

FIG. 1 is a perspective view illustrating an overall configuration of a substrate transfer apparatus according to Embodiment 1.

FIG. 2 is a perspective view illustrating an overall configuration of a gripping mechanism according to Embodiment 1.

FIG. 3 is a perspective view illustrating a movement of a branched blade according to Embodiment 1 in an upper-lower direction.

FIG. 4 is a perspective view illustrating a movement of the branched blade according to Embodiment 1 in the upper-lower direction.

FIG. 5 is a plan view for illustrating guides according to Embodiment 1.

FIG. 6 is a plan view for illustrating guides according to Embodiment 1.

FIG. 7 is a plan view for illustrating guides according to Embodiment 1.

FIG. 8 is a perspective view for illustrating a pusher according to Embodiment 1.

FIG. 9 is a plan view for illustrating the pusher according to Embodiment 1.

FIG. 10 is a cross-sectional view for illustrating a driving mechanism for the pusher according to Embodiment 1.

FIG. 11 is a perspective view for describing a pusher arm according to Embodiment 1.

FIG. 12 is a cross-sectional view for illustrating a driving mechanism for the pusher according to Embodiment 1.

FIG. 13 is a plan view for illustrating a substrate processing apparatus according to Embodiment 2.

FIG. 14 is a plan view for illustrating a modified example according to the invention.

FIG. 15 is a plan view for illustrating a modified example according to the invention.

### DESCRIPTION OF THE EMBODIMENTS

In view of the issues, the invention is configured as follows.

That is, a substrate transfer apparatus transfers a substrate. The substrate transferring apparatus includes: a first hand, able to grip a substrate in a horizontal orientation; a second hand, able to grip a substrate, different from the substrate, in a horizontal orientation; a holder, aligning the first hand and the second hand in a vertical direction and holding the first hand and the second hand; an arm, movably supporting the holder; and a base member, supporting the arm.

The first hand includes: a first blade; a pair of first proximal end guides, provided at a proximal end of the first blade and supporting the substrate by coming into contact with a bottom surface of the substrate; a pair of first distal end guides, provided at a distal end of the first blade and supporting the substrate by coming into contact with the bottom surface of the substrate; and a first pusher, provided for gripping the substrate, disposed at the proximal end of the first blade, and at a position sandwiched between the pair of first proximal end guides.

The second hand includes: a second blade; a pair of second proximal end guides, provided at a proximal end of the second blade and supporting the substrate by coming into contact with a bottom surface of the substrate; a pair of second distal end guides, provided at a distal end of the second blade and supporting the substrate by coming into contact with the bottom surface of the substrate; and a second pusher, provided for gripping the substrate, disposed at the proximal end of the second blade, at a position sandwiched between the pair of second proximal end guides. The first pusher includes a first member and a second member, each of the first member and the second member pressing the substrate forward by coming into abutment against the substrate, the second pusher includes a third member that presses the substrate forward by coming into abutment against the substrate, and the third member is at a position sandwiched between the first member and the second member in a plan view.

The first hand includes the first pusher for gripping a substrate, the first pusher being provided at a proximal end of the first blade and at a position sandwiched between the pair of first proximal end guides. The second hand includes the second pusher for gripping a substrate, the second pusher being provided at a position sandwiched between a pair of second proximal end guides. The first pusher includes the first member and the second member, against each of which the substrate comes into abutment, and the third member pertinent to the second pusher is provided at a position sandwiched between the first member and the second member. With the configuration, the first pusher and the second pusher are set to positions that are different from each other. Therefore, the pushers do not interfere with each other even if the first pusher and the second pusher are thickened in the vertical direction. According to the invention, it is possible to provide the substrate transfer apparatus that reliably transfers the substrate that is warped or thick by holding the substrate using the thick pushers.

In addition, in the substrate transfer apparatus, it may also be that the second hand is provided at a position not overlapping with the first hand in a plan view, the holder includes a lifting mechanism able to move the first hand and the second hand relatively to each other in the vertical direction, and the lifting mechanism is able to bring the first hand and the second hand to an in-flush state in which the first hand and the second hand are positioned on a same plane and to a separated state in which the first hand and the second hand are separated in the vertical direction.

With the configuration, the second hand is provided at a position not overlapping with the first hand in a plan view, the holder includes the lifting mechanism able to move the first hand and the second hand relatively with respect to each other in the vertical direction, and the lifting mechanism is able to position the first hand and the second hand in the in-flush state of being placed on the same plane, and in the separated state of separating the first hand and the second hand are separated from each other in the vertical direction. By moving the first hand and the second hand relatively with respect to each other in the vertical direction, the invention can also be applied to a substrate transfer apparatus capable of changing the number of substrates to be transferred.

In addition, in the substrate transfer apparatus, it may also be that the pair of first proximal end guides are respectively in a relationship line-symmetric to each other with respect to a virtual line halving a substrate that is circular in a plan view, the pair of first distal end guides are respectively in a relationship line-symmetric to each other with respect to the virtual line, the pair of second proximal end guides are respectively in a relationship line-symmetric to each other with respect to the virtual line, the pair of second distal end guides are respectively in a relationship line-symmetric to each other with respect to the virtual line, the first member and the second member in the first pusher are in a relationship line-symmetric to each other with respect to the virtual line, and the third member of the second pusher is on the virtual line.

With the configuration, the first proximal end guides are respectively in a relationship line-symmetric to each other with respect to the virtual line halving a substrate that is circular in a plan view; the first distal end guides are respectively in a relationship line-symmetric to each other with respect to the virtual line; the second proximal end guides are respectively in a relationship line-symmetric to each other with respect to the virtual line; the second distal end guides are respectively in a relationship line-symmetric to each other with respect to the virtual line; the first member and the second member in the first pusher are in a relationship line-symmetric to each other with respect to the virtual line, and the second pusher is on the virtual line. With the configuration, the first pusher presses the substrate from the left side and the right side, to press the substrate against the first distal end guides that are in a relationship line-symmetric to each other with respect to the virtual line. Furthermore, the third member pertinent to the second pusher presses the substrate from the center, so that the substrate is pressed against the pair of second distal end guides that are in a relationship line-symmetric to each other with respect to the virtual line IL. With the configuration, when gripping a viscous substrate, the position of the substrate is not deviated.

In addition, in the substrate transfer apparatus, it may also be that distal ends in the first member and the second member of the first pusher that come into abutment against a substrate have a shape conforming to a shape of the substrate, and a distal end in the third member of the second pusher that comes into abutment against the substrate has a shape conforming to the shape of the substrate.

With the configuration, each of the distal ends of the first member and the second member of the first pusher with which the substrate comes into abutment has a shape conforming to the shape of the substrate, and the distal end of the second pusher against which the substrate comes into abutment also has a shape conforming to the shape of the substrate. With the configuration, the first member and the second member of the first pusher can grip the substrate by using a wider contact surface. Therefore, the substrate is gripped more reliably by the first pusher. In the same manner, the distal end in the third member of the second pusher can grip the substrate with a wider contact surface. Therefore, the substrate is gripped more reliably by the second pusher.

In addition, in the substrate transfer apparatus, it may also be that the distal end of the first member protrudes in a direction orthogonal to a direction in which the first member moves, and the distal end of the second member protrudes in a direction orthogonal to a direction in which the second member moves.

With the configuration, the distal end of the first member protrudes in a direction orthogonal to the direction in which the first member moves, and the distal end of the second member protrudes in the direction orthogonal to the direction in which the second member moves. With the configuration, the first member and the second member of the first pusher can grip the substrate by using a wider contact surface. Therefore, the substrate is gripped more reliably by the first pusher.

In addition, the substrate transfer apparatus may further include: a first holder, having the first hand and the second hand; and a second holder, having two hands similar to the first hand and the second hand, and provided to be separated from the first holder in the vertical direction.

With the configuration, the first holder having the first hand and the second hand and the second holder having the first hand and the second hand and provided to be separated from the first holder in the vertical direction. With the configuration, a larger number of substrates can be transferred simultaneously.

In addition, in the substrate transfer apparatus, it may also be that the first hand includes a first driving mechanism able to move the first member and the second member forward and backward with respect to the substrate while maintaining relative positions of the first member and the second member, and the second hand includes a second driving mechanism able to move the third member forward and backward with respect to the substrate.

With the configuration according to the embodiment, the first hand includes the first driving mechanism able to move the first member and the second member closer to the substrate while maintaining the relative positions of the first member and the second member, and the second hand includes the second driving mechanism able to move the third member closer to the substrate. With the configuration, by moving the first member and the second member closer to the substrate synchronously, the first driving mechanism causes the first hand to grip the substrate. As a result, the substrate is gripped by receiving the same forces on the left and the right sides thereof, respectively. With the configuration described above, the substrate can be gripped reliably.

In addition, in the substrate transfer apparatus, it may also be that the first driving mechanism includes: a first power unit, generating power; and a first pusher arm, transmitting the power of the first power unit to the first member and the second member of the first pusher, the second driving mechanism includes a second power unit that generates power at a position separated from the first power unit in the vertical direction, and the second driving mechanism includes, at a position avoiding the first pusher arm, a second pusher arm that transmits the power of the second power unit to the third member of the second pusher.

With the configuration, the first driving mechanism includes: the first power unit that generates power; and the first pusher arm that transmits the power of the first power unit to the first member and the second member of the first pusher. The second driving mechanism includes: the second power unit that generates power at a position separated from the first power unit in the vertical direction, and the second driving mechanism includes the second pusher arm that transmits the power of the second power unit to the third member of the second pusher at a position avoiding the first pusher arm. With the configuration, the substrate transfer apparatus can be configured by stacking the power units in the vertical direction, and the configuration according to the present invention can be achieved without a significant change in the design of a conventional apparatus.

In addition, the specification also discloses a substrate processing apparatus including the substrate transfer apparatus. The substrate processing apparatus includes a single wafer processing chamber that performs a predetermined process on the substrate.

The invention relates to a substrate transfer apparatus capable of transferring multiple horizontally oriented substrates simultaneously, and a substrate processing apparatus including the substrate transfer apparatus.

Embodiments of the invention will now be described with reference to drawings. The substrate transfer apparatus according to the invention has a configuration capable of receiving and to transferring four horizontally oriented substrates that are vertically aligned, simultaneously.

### Embodiment 1

### 1. Overall Configuration

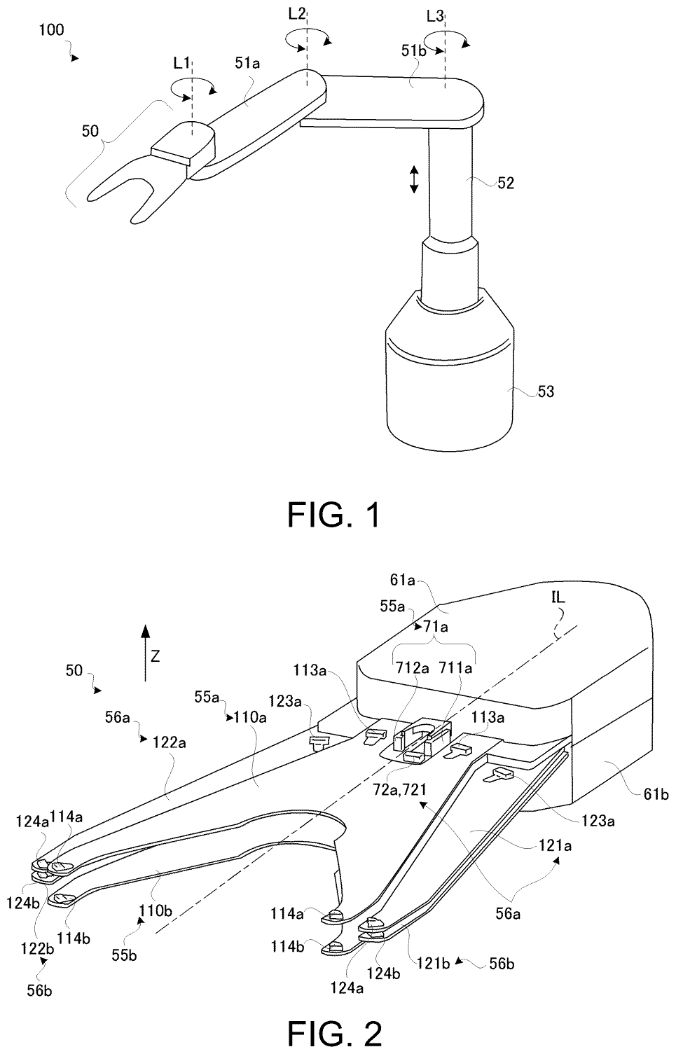

FIG. 1 illustrates a substrate transfer apparatus 100 according to the embodiment. The substrate transfer apparatus 100 according to the embodiment includes a gripping mechanism 50 able to grip four substrates W in a horizontal orientation, individually. The gripping mechanism 50 is supported on an elongated arm 51a extending in the horizontal direction. The gripping mechanism 50 and the arm 51a are connected to each other via a joint. The joint allows the gripping mechanism 50 to rotate about a vertical axis L1, with respect to the arm 51a. The arm 51a movably supports a holder 61a and a holder 61b, to be described later, that are provided at the gripping mechanism 50.

The distal end of the arm 51a is provided with the gripping mechanism 50. The proximal end of the arm 51a is connected to an elongated arm 51b extending in the horizontal direction. The arm 51a and the arm 51b are connected via a joint. The joint allows the arm 51a to rotate about a vertical axis L2 with respect to the arm 51b.

The distal end of the arm 51b is connected to the arm 51a. The proximal end of the arm 51b is connected to a main shaft 52 extending in the vertical direction. The main shaft 52 is able to extend and contract. By arranging the main shaft 52 to extend and to contract, the height of the gripping mechanism 50 in the vertical direction is changed. The arm 51b and the main shaft 52 are connected via a joint. The joint allows the arm 51b to rotate about a vertical axis L3 with respect to the main shaft 52.

A robot base 53 is configured to support the main shaft 52. The robot base 53 forms the bottom part of the substrate transfer apparatus 100. The robot base 53 is a base member that supports the arm 51a and the arm 51b.

### 2. Overview of Gripping Member

FIG. 2 is a perspective view illustrating a general configuration of the gripping mechanism 50 according to the embodiment. The gripping mechanism 50 is provided with four hands for gripping horizontally oriented substrates W. The gripping mechanism 50 has two holders 61a and 61b that are disposed to be opposite to each other in the upper-lower direction. The holder 61a on the upper side holds the first hand 55a and the second hand 56a. The holder 61b on the lower side holds the first hand 55b and the second hand 56b. The first hand 55a and the second hand 56a on the upper side are used for transferring substrates having been processed, for example. The first hand 55b and second hand 56b on the lower side are used for transferring substrates to be processed, for example. As described above, in the embodiment, by using the hands selectively depending on the application of transfer (substrates to be processed and having been processed), the contamination between the substrates is prevented. By transferring two substrates of the same application simultaneously by using two hands, processing efficiency is increased.

By bringing the first hand 55a and the second hand 56a in flush with each other so as to be positioned on the same plane in the vertical direction, the holder 61a can achieve a configuration suitable for transferring only one substrate W to be processed. When gripping one substrate W, one of the first hand 55a and the second hand 56a is folded, so that the hand does not collide with a carrier carrying the substrate W to be gripped (e.g., a carrier C to be described later). In the same manner, by bringing the first hand 55b and the second hand 56b in flush with each other, the holder 61b can achieve a configuration suitable for transferring only one processed substrate W. In this manner, the holder 61b is provided with a configuration achieving the same effect as that achieved by the holder 61a.

The first hand 55a will now be described. As illustrated in FIG. 2, the first hand 55a includes a first branched blade 110a, a pair of first proximal end guides 113a, a pair of first distal end guides 114a, and a first pusher 71a. The distal end of the first branched blade 110a is branched into two. The first hand 55a is configured to grip the substrate W by pressing the substrate W supported on the top surface of the first branched blade 110a by using the first pusher 71a.

As illustrated in FIG. 2, the second hand 56a includes a first blade piece 121a and a second blade piece 122a extending in the horizontal direction, a pair of second proximal end guides 123a, a pair of second distal end guides 124a, and a second pusher 72a. The second hand 56a is configured to press the substrate W supported on the top surfaces of the first blade piece 121a and the second blade piece 122a by using the second pusher 72a.

In the same manner as the first hand 55a, the first hand 55b includes a branched blade 110b, a pair of first proximal end guides 113b, a pair of first distal end guides 114b, and a first pusher 71b. The first hand 55b is configured to grip the substrate W by arranging the first pusher 71b to push the substrate W supported on the top surface of the branched blade 110b.

In the same manner as the second hand 56a, the second hand 56b includes a first blade piece 121b, a second blade piece 122b, a pair of second proximal end guides 123b, a pair of second distal end guides 124b, and a second pusher 72b. The second hand 56b is configured to press the substrate W supported on the top surfaces of the first blade piece 121b and the second blade piece 122b, using the second pusher 72b.

The holder 61a is a blade supporting unit connected to the proximal ends of the branched blade 110a, the first blade piece 121a, and the second blade piece 122a. The holder 61b is a blade supporting unit connected to the proximal ends of the branched blade 110b, the first blade piece 121b, and the second blade piece 122b, which will be described later. In the gripping mechanism 50, the holder 61a and the holder 61b are stacked in the vertical direction. The holder 61a holds the first hand 55a and the second hand 56a in a manner aligned in the vertical direction Z. In the same manner, the holder 61b holds the first hand 55b and the second hand 56b in a manner aligned in the vertical direction Z. The holder 61b is provided in a manner spaced apart from the holder 61a in the vertical direction The holder 61b is provided in a manner separated from the holder 61a in the vertical direction.

In a plan view, the proximal end of the branched blade 110a and the proximal end of the branched blade 110b are at the same position. The branched blade 110a and the branched blade 110b have the same shape, and extend in the same direction. The branched blade 110a is positioned above the branched blade 110b. Therefore, in a plan view, the branched blade 110b is hidden behind the branched blade 110a. The branched blade 110a has a laterally symmetric shape with respect to a virtual line IL passing through the proximal end thereof. The same applies to the branched blade 110b.

In a plan view, the proximal end of the first blade piece 121a and the proximal end of the first blade piece 121b are at the same position. The first blade piece 121a and the first blade piece 121b have the same shape, and extend in the same direction. The first blade piece 121a is positioned above the first blade piece 121b. Therefore, in a plan view, the first blade piece 121b is hidden behind the first blade piece 121a.

In a plan view, the proximal end of the second blade piece 122a and the proximal end of the second blade piece 122b are at the same position. The second blade piece 122a and the second blade piece 122b have the same shape, and extend in the same direction. The second blade piece 122a is positioned above the second blade piece 122b. Therefore, in a plan view, the second blade piece 122b is hidden behind the second blade piece 122a.

The first blade piece 121a and the second blade piece 122a have shapes that are mirror-symmetric to each other with respect to the virtual line IL. The same applies to the first blade piece 121b and the second blade piece 122b.

### 3. About Stacked Four Hands

As described above, the gripping mechanism 50 according to the embodiment has a configuration able to grip four substrates W simultaneously. In other words, the gripping mechanism 50 has a configuration including four different hands that are aligned in the vertical direction. The branched blade 110a pertinent to the first hand 55a is in the uppermost layer of the gripping mechanism 50. The branched blade 110a can hold a substrate W in a horizontal orientation.

The first blade piece 121a and the second blade piece 122a are positioned in an upper middle layer that is lower than the branched blade 110a. The first blade piece 121a and the second blade piece 122a are at the same position in the vertical direction. The first blade piece 121a and the second blade piece 122a can hold the substrate W in the horizontal orientation by each holding one side of the substrate W.

The first blade piece 121b and the second blade piece 122b pertinent to the second hand 56b are positioned in a lower middle layer that is lower than the first blade piece 121a and the second blade piece 122a pertinent to the second hand 56a in the upper middle layer. The first blade piece 121b and the second blade piece 122b are at the same position in the vertical direction. The first blade piece 121b and the second blade piece 122b can hold the substrate W in the horizontal orientation by each holding one side of the substrate W.

The branched blade 110b pertinent to the first hand 55b is positioned in the lowermost layer in the gripping mechanism 50, and that is lower than the first blade piece 121b and the second blade piece 122b pertinent to the lower middle layer. The branched blade 110b can hold the substrate W in the horizontal orientation.

The upper-lower movement of the branched blade 110a pertinent to the uppermost layer will now be described. The branched blade 110a is able to move in the vertical directions with respect to the first blade piece 121a and the second blade piece 122a pertinent to the upper middle layer. In other words, the branched blade 110a is able to be displaced between a position higher than the first blade piece 121a and the second blade piece 122a, and a position that is same as those of the first blade piece 121a and the second blade piece 122a in the vertical direction.

The branched blade 110b pertinent to the lowermost layer is also able to move in the vertical directions with respect to the first blade piece 121b and the second blade piece 122b pertinent to the lower middle layer. In other words, the branched blade 110b is able to be displaced between a position lower than the first blade piece 121b and the second blade piece 122b, and a position that is the same as those of the first blade piece 121b and the second blade piece 122b in the vertical direction.

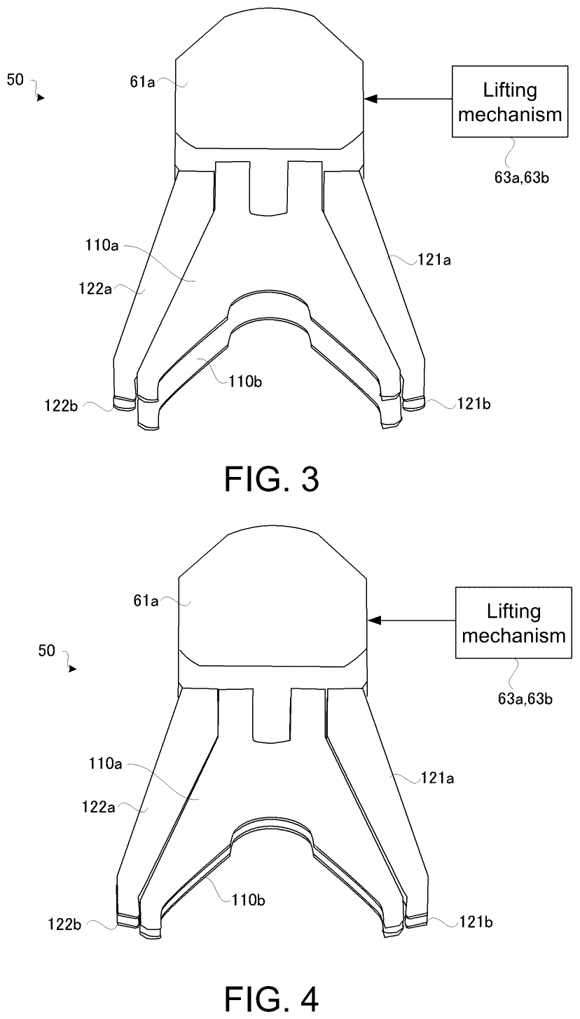

FIG. 3 is a perspective view illustrating the branched blade 110a pertinent to the uppermost layer, in a manner separated from the first blade piece 121a and the second blade piece 122a pertinent to the upper middle layer. In FIG. 3, the branched blade 110b pertinent to the lowermost layer is also separated from the first blade piece 121b and the second blade piece 122b pertinent to the lower middle layer.

FIG. 4 is a perspective view illustrating the branched blade 110a on the same plane as the first blade piece 121a and the second blade piece 122a in the upper middle layer. In FIG. 4, the branched blade 110b is also on the same plane as the first blade piece 121b and the second blade piece 122b in the lower middle layer.

Such upper-lower movement of the branched blade 110a is implemented by a lifting mechanism 63a provided at the holder 61a, and by a lifting mechanism 63b provided at the holder 61b. As described above, the holder 61a includes the lifting mechanism 63a able to move the first hand 55a and the second hand 56a relatively with respect to each other in the vertical direction Z. The lifting mechanism 63a can bring the first hand 55a and the second hand 56a to the positions on the same plane. The lifting mechanism 63a can also separate the first hand 55a and the second hand 56a from each other in the vertical direction Z. The holder 61b also includes the lifting mechanism 63b having a similar function.

The lifting mechanism 63a can switch between a configuration suitable for holding only one substrate W, in which the first hand 55a and the second hand 56a are in flush with each other, and a configuration suitable for holding two substrates W, in which the first hand 55a and the second hand 56a are separated from each other in the upper-lower direction.

By arranging the branched blade 110a and the branched blade 110b to operate synchronously to each other, the lifting mechanism 63a and the lifting mechanism 63b form the two configurations, one of which is the configuration illustrated in FIG. 3 in which the branched blade 110a and the branched blade 110b are separated from each other maximumly, and the other one of which is the configuration illustrated in FIG. 4 in which the branched blade 110a and the branched blade 110b are brought closest to each other. The gripping mechanism 50 in the configuration illustrated FIG. 3 can grip four substrates W in the horizontal orientation simultaneously, and the gripping mechanism 50 in the configuration illustrated in FIG. 4 can hold two substrates W in the horizontal orientation simultaneously.

The lifting mechanism 63b can switch between a configuration suitable for holding only one substrate W, in which the first hand 55b and the second hand 56b are in flush with each other, and a configuration suitable for holding two substrates W, in which the first hand 55b and the second hand 56b are separated from each other in the upper-lower direction.

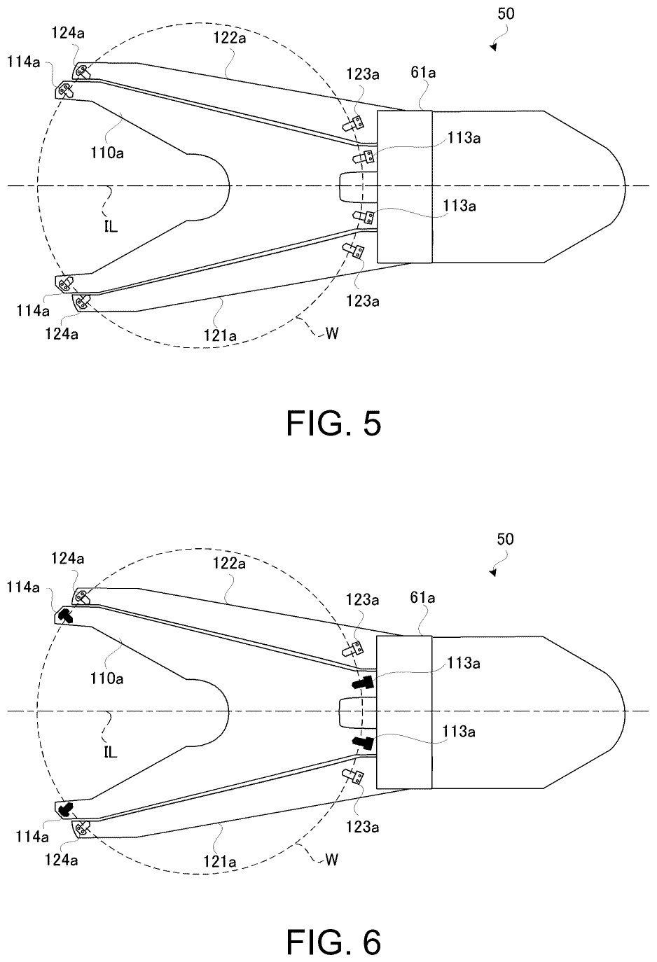

In order to achieve such upper-lower movement, the branched blade 110a pertinent to the uppermost layer has a property by its shape. In other words, as can be seen by referring the plan view in FIG. 5, the branched blade 110a and the first blade piece 121a pertinent to the upper middle layer are at positions not overlapping each other in a plan view. The same applies to the branched blade 110a and the second blade piece 122a. With the configuration, the branched blade 110a does not collide with the first blade piece 121a when the branched blade 110a is brought to the upper middle layer. The same applies to the second blade piece 122a. The second hand 56a is provided at a position not overlapping with the first hand 55a in a plan view.

In the same manner, the branched blade 110b pertinent to the lowermost layer and the first blade piece 121b pertinent to the lower middle layer are at positions not overlapping each other in a plan view. The same applies to the branched blade 110b and the second blade piece 122b. In other words, the second hand 56b is provided at a position not overlapping with the first hand 55b in a plan view. With such a configuration, the same effect as that achieved by the branched blade 110a is also achieved by the branched blade 110b.

### 4. About Guides

The guides of the branched blade 110a pertinent to the uppermost layer will be described. On the top surface of the branched blade 110a, four guides are provided. In other words, to the proximal end of the branched blade 110a, a pair of first proximal end guides 113a are provided. To the distal end of the branched blade 110a, a pair of first distal end guides 114a are provided. The branched blade 110a has two branches extending toward the distal end, and the first distal end guides 114a are provided at the respective branches. The pair of first proximal end guides 113a and the pair of first distal end guides 114a respectively come into abutment against the bottom surface of the substrate W. The pair of first proximal end guides 113a and the pair of first distal end guides 114a are protrusions that are provided on the top surface of the branched blade 110a. Therefore, the substrate W is supported at four points on the pair of first proximal end guides 113a and the pair of first distal end guides 114a.

As can be seen by referring to the plan view in FIG. 5, the pair of first proximal end guides 113a provided at the branched blade 110a are at positions laterally symmetric to each other with respect to the virtual line IL. In other words, the pair of first proximal end guides 113a are line-symmetric to each other with respect to the virtual line IL. In the same manner, the pair of first distal end guides 114a provided on the branched blade 110a are at positions laterally symmetric to each other with respect to the virtual line IL. In other words, the pair of first distal end guides 114a are line-symmetric to each other with respect to the virtual line IL. As a result, the branched blade 110a can support one side and the other side of the substrate W under the same condition, the one side and the other side being halved along the virtual line IL, so that the substrate W being pressed by the first pusher 71a, to be described later, does not rotate.

The branched blade 110b pertinent to the lowermost layer is also provided with four guides. The four guides are similar to those on the branched blade 110a. In other words, a pair of first proximal end guides 113b are provided at the proximal end of the branched blade 110b, and a pair of first distal end guides 114b are provided at the distal end of the branched blade 110b. In the same manner as the branched blade 110a, the pair of first proximal end guides 113b are provided to be laterally symmetric to each other with respect to the virtual line IL, and the pair of first distal end guides 114b are provided to be laterally symmetric to each other with respect to the virtual line IL. In other words, the pair of first proximal end guides 113b are line-symmetric to each other with respect to the virtual line IL. In the same manner, the pair of first distal end guides 114b are line-symmetric to each other with respect to the virtual line IL.

The first hand 55a is provided with: the pair of first proximal end guides 113a with which the bottom surface of the substrate W comes into contact, at the proximal end thereof; and the pair of first distal end guides 114a with which the bottom surface of the substrate W comes into contact, at the distal end thereof. In the same manner, the first hand 55b is provided with: the pair of first proximal end guides 113b with which the bottom surface of the substrate W comes into contact, at the proximal end thereof; and the pair of first distal end guides 114b with which the bottom surface of the substrate W comes into contact, at the distal end thereof.

The guides on the first blade piece 121a and the second blade piece 122a pertinent to the upper middle layer will now be described. As illustrated in FIG. 2, the top surfaces of the first blade piece 121a and the second blade piece 122a are provided with four guides in total. In other words, the second proximal end guides 123a are provided at the proximal ends of the first blade piece 121a and the second blade piece 122a, respectively. The second distal end guides 124a are provided at the distal ends of the first blade piece 121a and the second blade piece 122a, respectively.

As can be seen by referring to the plan view in FIG. 5, the pair of second proximal end guides 123a provided on the first blade piece 121a and the second blade piece 122a are at positions laterally symmetric to each other with respect to the virtual line IL. In other words, the pair of second proximal end guides 123a are line-symmetric to each other with respect to the virtual line IL. In the same manner, the pair of second distal end guides 124a provided on the first blade piece 121a and the second blade piece 122a are at positions symmetric to each other with respect to the virtual line IL. In other words, the pair of second distal end guides 124a are line-symmetric to each other with respect to the virtual line IL. As a result, the first blade piece 121a and the second blade piece 122a can support one side and the other side of the substrate W under the same condition, the one side and the other side being halved along the virtual line IL, so that the substrate W pressed by the second pusher 72a, to described later, does not rotate.

The first blade piece 121b and the second blade piece 122b pertinent to the lower middle layer are also provided with four guides, in the same manner as the first blade piece 121a and the second blade piece 122a pertinent to the upper middle layer. In other words, the pair of second proximal end guides 123b are provided at the proximal ends of the first blade piece 121b and the second blade piece 122b, respectively, and the pair of second distal end guides 124b are provided at the distal ends of the first blade piece 121b and the second blade piece 122b. The pair of second proximal end guides 123b are provided to be laterally symmetric to each other with respect to the virtual line IL, and the pair of second distal end guides 124b are provided to be laterally symmetric to each other with respect to the virtual line IL, in the same manner as the first blade piece 121a and the second blade piece 122a. In other words, the pair of second proximal end guides 123b are line-symmetric to each other with respect to the virtual line IL. In the same manner, the pair of second distal end guides 124b are line-symmetric to each other with respect to the virtual line IL.

The second hand 56a is provided with: the pair of second proximal end guides 123a with which the bottom surface of the substrate W comes into contact, at the proximal end thereof; and the pair of second distal end guides 124a with which the bottom surface of the substrate W comes into contact, at the distal end thereof. In the same manner, the second hand 56b is provided with: the pair of second proximal end guides 123b with which the bottom surface of the substrate W comes into contact, at the proximal end thereof, and the pair of second distal end guides 124b with which the bottom surface of the substrate W comes into contact, at the distal end thereof.

Depending on the position at which the branched blade 110a is located, the guides against which the substrate W comes into abutment change, the configuration will now be described. The plan view in FIG. 6 illustrates a configuration in which the branched blade 110a pertinent to the uppermost layer holds the substrate W, with four guides of the pair of first proximal end guides 113a and the pair of first distal end guides 114a. Because both of the second proximal end guides 123a and the second distal end guides 124a included in the first blade piece 121a and the second blade piece 122a pertinent to the upper middle layer are lower than the branched blade 110a, the second proximal end guides 123a and the second distal end guides 124a do not come into abutment against the substrate W supported by the branched blade 110a.

The same applies to the branched blade 110b pertinent to the lowermost layer. The branched blade 110b pertinent to the lowermost layer holds the substrate W with four guides of the pair of first proximal end guides 113b and the pair of first distal end guides 114b. Because both of the second proximal end guides 123b and the second distal end guides 124b included in the first blade piece 121b and the second blade piece 122b pertinent to the lower middle layer are higher than the branched blade 110b, the second proximal end guides 123b and the second distal end guides 124b do not come into abutment against the substrate W supported by the branched blade 110b.

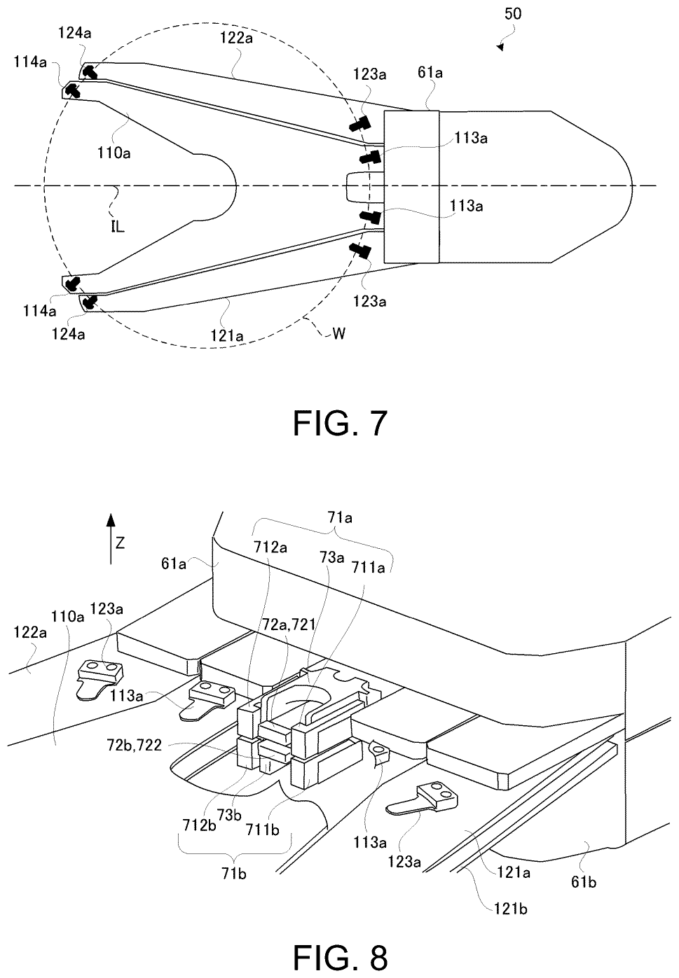

Comparatively, the plan view in FIG. 7 illustrates a configuration in which the branched blade 110a is positioned on the same plane as the upper middle layer. The branched blade 110a in the configuration supports one substrate W in the horizontal orientation, together with the first blade piece 121a and the second blade piece 122a. Therefore, the substrate W abuts against the eight guides of the pair of first proximal end guides 113a, the pair of first distal end guides 114a, the pair of second proximal end guides 123a, and the pair of second distal end guides 124a.

The same applies to the branched blade 110b positioned on the same plane as the lower middle layer. The branched blade 110b in the configuration supports one substrate W in the horizontal orientation, together with the first blade piece 121b and the second blade piece 122b. Therefore, the substrate W abuts against the eight guides of the pair of first proximal end guides 113b, the pair of first distal end guides 114b, the pair of second proximal end guides 123b, and the pair of second distal end guides 124b.

The substrate W having come into abutment against the eight guides of the branched blade 110a is pressed and gripped by the first pusher 71a or the second pusher 72a, to be described later. Furthermore, the substrate W having come into abutment against the eight guides of the branched blade 110b is pressed and gripped by the first pusher 71b or the second pusher 72b, to be described later.

### 5. About Pushers

Pushers will now be described. FIG. 8 illustrates the first pusher 71a of the first hand pertinent to the branched blade 110a, and the second pusher 72a of the second hand pertinent to the first blade piece 121a and the second blade piece 122a.

To begin with, the first pusher 71a will be described. The first pusher 71a is a substrate gripping member disposed at the proximal end of the first hand 55a, which is a position sandwiched between the pair of first proximal end guides 113a. The first pusher 71a includes: a first member 711a and a second member 712a having thicknesses in the vertical direction Z; and a coupling member 73a that bridges the first member 711a and the second member 712a. The first member 711a and the second member 712a are integrated by the coupling member 73a. The first member 711a and the second member 712a are members thicker in the vertical direction Z than the width in the direction from the first member 711a toward the second member 712a.

The first pusher 71a is provided with the coupling member 73a on a ceiling surface, as well as the first member 711a and the second member 712a as side walls in the coupling member 73a, the side walls extending in a direction in which the first pusher 71a moves forward and backward. A space surrounded by the coupling member 73a, the first member 711a, and the second member 712a is thus formed. In the space, a third member 721 of the second pusher 72a, to be described later, is housed.

The first pusher 71a can move forward and backward with respect to the substrate W, and to transition between a closing state in which the distal end of the first member 711a and the distal end of the second member 712a are simultaneously brought into contact with the substrate W, and an open state in which the distal end of the first member 711a and the distal end of the second member 712a are separated from the substrate W.

The second pusher 72a will now be described. The third member 721 of the second pusher 72a is a substrate gripping member disposed at the proximal end of the second hand 56a, which is a position sandwiched between the pair of second proximal end guides 123a. Unlike the first member 711a and the second member 712a of the first pusher 71a, the third member 721 of the second pusher 72a is a member in which the width in the direction from the first member 711a toward the second member 712a is larger than the thickness in the vertical direction Z. As described above, the third member 721 of the second pusher 72a is positioned in the space surrounded by the coupling member 73a, the first member 711a, and the second member 712a. In other words, the third member 721 of the second pusher 72a is at a position sandwiched between the first member 711a and the second member 712a of the first pusher 71a.

The third member 721 of the second pusher 72a is able to move forward and backward with respect to the substrate W, and to transition between the closing state in which the distal end comes into contact with the substrate W and the open state in which the distal end is separated from the substrate W.

Because the first pusher 71a is attached to the first hand 55a including the branched blade 110a, the first pusher 71a is configured to follow the upper-lower movement of the branched blade 110a. In FIG. 8, because the branched blade 110a is on the same plane as the first blade piece 121a and the second blade piece 122a, the first pusher 71a is at the same position as the second pusher 72a in the vertical direction. When the branched blade 110a is moved up to the uppermost layer, the first pusher 71a is also moved up and is separated from the second pusher 72a. The configuration is illustrated in FIG. 2.

FIG. 8 also illustrates the first pusher 71b of the first hand 55a pertinent to the branched plate 110a, and the second pusher 72b of the second hand pertinent to the first blade piece 121b and the second blade piece 122b.

The first pusher 71b pertinent to the lowermost layer has the same configuration as the first pusher 71a pertinent to the uppermost layer, but the first pusher 71b is located below the first pusher 71a and has a shape in which the first pusher 71a is inverted in the upper-lower direction. The first pusher 71b is provided with a coupling member 73b on a bottom surface, as well as a first member 711b and a second member 712b as side walls in the coupling member 73a, the side walls extending in a direction in which the first pusher 71b moves forward and backward. The second pusher 72b, to be described later, is housed in a space surrounded by the coupling member 73b, the first member 711b, and the second member 712b.

In the same manner as the first pusher 71a, the first pusher 71b is able to move forward and backward with respect to the substrate W, and to transition between the closing state and the open state. The first pusher 71b is a substrate gripping member disposed at the proximal end of the first hand 55b, which is a position sandwiched between the pair of first proximal end guides 113b.

The third member 722 of the second pusher 72b pertinent to the lower middle layer has the same configuration as the second pusher 72a pertinent to the upper middle layer. The third member 722 of the second pusher 72b can be positioned in the space surrounded by the coupling member 73b, the first member 711b, and the second member 712b. In other words, the third member 722 of the second pusher 72b is at a position sandwiched between the first member 711b and the second member 712b of the first pusher 71b.

The second pusher 72b is also able to move forward and backward with respect to the substrate W, and to transition between the closing state and the open state. The second pusher 72b is a substrate gripping member disposed at the proximal end of the second hand 56b, which is a position sandwiched between the pair of second proximal end guides 123b.

Because the first pusher 71b is attached to the first hand including the branched blade 110b, the first pusher 71b is configured to follow the upper-lower movement of the branched blade 110b. In FIG. 8, because the branched blade 110b is on the same plane as the first blade piece 121a and the second blade piece 122a, the first pusher 71a is at the same position as the second pusher 72b in the vertical direction. When the branched blade 110b is moved down to the lowermost layer, the first pusher 71a is also moved down and is separated from the second pusher 72a.

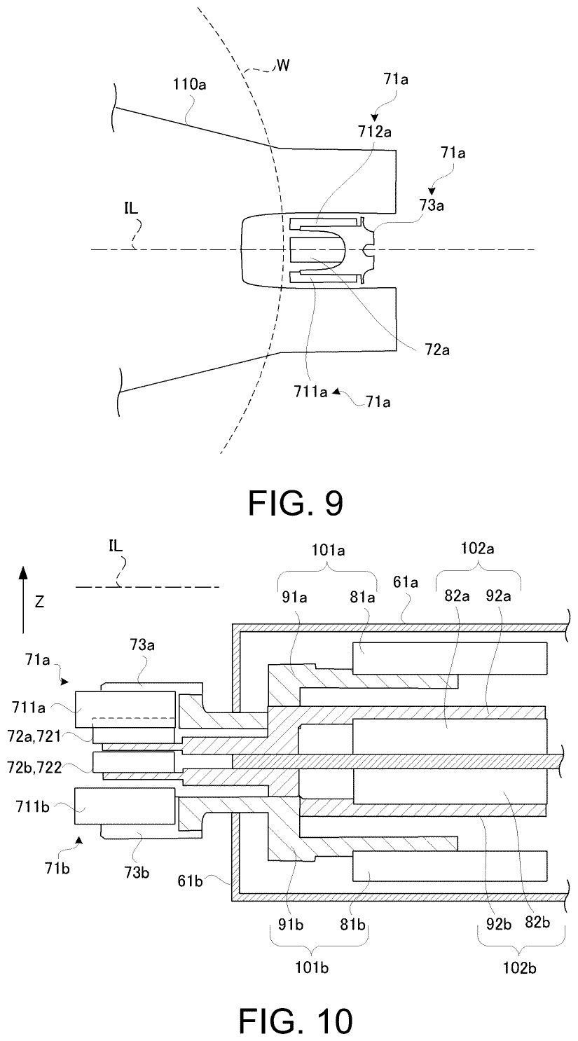

As can be seen by referring to the plan view in FIG. 9, the first member 711a and the second member 712a provided on the first pusher 71a pertinent to the uppermost layer are at positions laterally symmetric to each other with respect to the virtual line IL. In other words, the first member 711a and the second member 712a are at line-symmetric positions to each other with respect to the virtual line IL. As a result, because the first pusher 71a can press one side and the other side of the substrate W under the same condition, the one side and the other side being halved along the virtual line IL, the substrate W does not rotate at the time of being pressed.

FIG. 9 also illustrates the second pusher 72a in the upper middle layer. The second pusher 72a is positioned on the virtual line IL. As a result, because the second pusher 72a can press one side and the other side of the substrate W under the same condition, the one side and the other side being halved along the virtual line IL, the substrate W does not rotate at the time of being pressed.

In the first pusher 71b pertinent to the lowermost layer, the first member 711b and the second member 712b are at positions symmetric to each other with respect to the virtual line IL, in the same manner as in the first pusher 71a. In other words, the first member 711b and the second member 712b are at positions line-symmetric to each other with respect to the virtual line IL. As a result, the first pusher 71b also achieves the same effect as that achieved by the first pusher 71a. The second pusher 72b pertinent to the lower middle layer is also on the virtual line IL, in the same manner as the second pusher 72a. As a result, the second pusher 72b also achieves the same effect as that achieved by the second pusher 72a.

### 6. About Pusher Driving Mechanism

FIG. 10 illustrates a driving mechanism realizing opening and closing operations of the pusher. The driving mechanism pertinent to the pusher is housed inside the holder 61a. A first driving mechanism 101a pertinent to the operation of the first pusher 71a includes a first power unit 81a that generates power, and a first pusher arm 91a that transmits the power of the first power unit 81a to the first pusher 71a.

The first hand 55a includes the first driving mechanism 101a able to move the first member 711a and the second member 712a closer to the substrate W while maintaining the relative positions thereof. The first driving mechanism 101a then includes: the first power unit 81a that generates power; and the first pusher arm 91a that transmits the power of the first power unit 81a to the first pusher 71a. The first power unit 81a is configured as an air cylinder, for example. The same applies to other power units 82a, 81b, and 82b.

The first power unit 81a can move the first pusher arm 91a forward and backward in the direction in which the virtual line IL extends. The first power unit 81a is a rectangular parallelepiped member extending along the virtual line IL. The first power unit 81a includes: a proximal part that is fixed to the holder 61a and does not move, and a moving part that is supported by the proximal part. The moving part can move forward and backward in the direction in which the virtual line IL extends by a power generator provided at the proximal part. The first pusher arm 91a has the proximal end connected to the moving part, and is able to move forward and backward with the moving part. Because the distal end of the first pusher arm 91a is connected to the coupling member 73a pertinent to the first pusher 71a, the first power unit 81a can move the coupling member 73a, the first member 711a, and the second member 712a forward and backward, by moving the moving part. The first pusher 71a can transition between the open state and the closing state on the basis of such a principle.

The second driving mechanism 102a pertinent to the operation of the second pusher 72a includes a second power unit 82a that generates power, and a second pusher arm 92a that transmits the power of the second power unit 82a to the third member 721 of the second pusher 72a. The second power unit 82a can move the third member 721 of the second pusher arm 92a forward in a direction extending in the virtual line IL. The second power unit 82a is a rectangular parallelepiped member extending along the virtual line IL. The second power unit 82a includes, in the same manner as the first power unit 81a, the following: a proximal part that is fixed to the holder 61a and does not move; and a moving part that is supported by the proximal part. The moving part can move forward and backward in the direction in which the virtual line IL extends by a power generator provided at the proximal part. The second pusher arm 92a has the proximal end connected to the moving part, and is able to move forward and backward with the moving part. Because the distal end of the second pusher arm 92a is connected to the second pusher 72a, the second power unit 82a can move the second pusher 72a forward and backward, by moving the moving part. The second pusher 72a can transition between the open state and the closing state on the basis of such a principle.

The second hand 56a includes the second driving mechanism 102a able to move the third member 721 of the second pusher 72a forward and backward with respect to the substrate W. The second driving mechanism 102a includes the second power unit 82a that generates power at a position separated from the first power unit 81a in the vertical direction Z. The second driving mechanism 102a includes the second pusher arm 92a that transmits the power of the second power unit 82a to the third member 721 of the second pusher 72a, at a position avoiding the first pusher arm 91a.

The first power unit 81a and the second power unit 82a are stacked in the vertical direction Z. In other words, the first power unit 81a is disposed above the second power unit 82a.

FIG. 10 also illustrates how the driving mechanism pertinent to the pusher is provided inside the holder 61b. The first driving mechanism 101b pertinent to the operation of the first pusher 71b includes: the first power unit 81b that generates power; and a first pusher arm 91b that transmits the power of the first power unit 81b to the first pusher 71b. The first power unit 81b has the same configuration as that of the first power unit 81a, and the first pusher arm 91b has the same configuration as that of the first pusher arm 91a. Therefore, the first power unit 81b can move the coupling member 73b, the first member 711b, and the second member 712b forward and backward, by moving the moving part. The first pusher 71b can transition between the open state and the closing state on the basis of such principle.

The first hand 55b includes the first driving mechanism 101b able to move the first member 711b and the second member 712b closer to the substrate W while maintaining the relative positions thereof. The first driving mechanism 101b includes the first power unit 81b that generates power, and the first pusher arm 91b that transmits the power of the first power unit 81b to the first pusher 71b.

The second driving mechanism 102b pertinent to the operation of the second pusher 72b includes the second power unit 82b that generates power, and a second pusher arm 92b that transmits the power of the second power unit 82b to the second pusher 72b. The second power unit 82b has the same configuration as that of the second power unit 82a, and the second pusher arm 92b has the same configuration as that of the second pusher arm 92a. Therefore, the second power unit 82b can move the second pusher 72b forward and backward, by moving the moving part. The second pusher 72b can transition between the open state and the closing state on the basis of such a principle.

The second hand 56b includes the second driving mechanism 102b able to move the second pusher 72b closer to the substrate W. The second driving mechanism 102b includes the second power unit 82b that generates power at a position spaced apart from the first power unit 81b in the vertical direction Z. The second driving mechanism 102b includes the second pusher arm 92b that transmits the power of the second power unit 82b to the second pusher 72b, at a position avoiding the first pusher arm 91b.

The first power unit 81b and the second power unit 82b are stacked in the vertical direction Z. In other words, the first power unit 81b is disposed below the second power unit 82b. The second power unit 82b is then positioned below the second power unit 82a. Therefore, the first power unit 81a, the second power unit 82a, the second power unit 82b, and the first power unit 81b are thus stacked in this order.

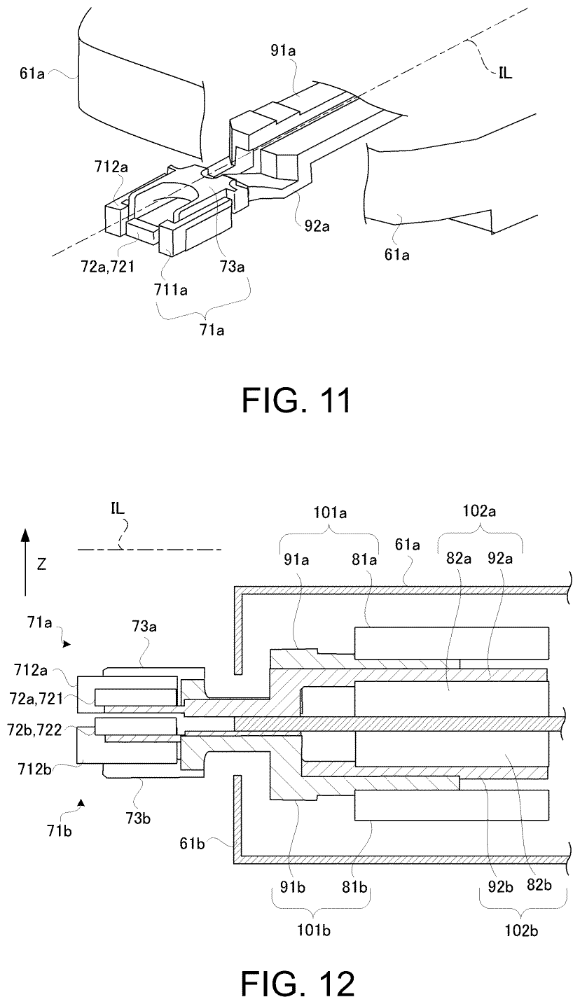

Because the first pusher arm 91a and the second pusher arm 92a are provided in a manner of avoiding each other, the configuration will now be described. FIG. 11 is a perspective view for describing a positional relationship between the first pusher arm 91a and the second pusher arm 92a. The first pusher arm 91a connected to the first pusher 71a and the second pusher arm 92a connected to the second pusher 72a are provided at positions laterally symmetric to each other with respect to the virtual line IL. Therefore, when the first pusher arm 91a is moved forward and backward, the first pusher arm 91a does not collide with the second pusher arm 92a. Furthermore, when the second pusher arm 92a is moved forward and backward, the second pusher arm 92a does not collide with the first pusher arm 91a.

While not shown in the drawings, the first pusher arm 91b and the second pusher arm 92b pertinent to the holder 61b are provided at positions that are left-right symmetric with respect to the virtual line IL. Therefore, when the first pusher arm 91b is moved forward and backward, the first pusher arm 91b does not collide with the second pusher arm 92b. Furthermore, when the second pusher arm 92b is moved forward and backward, the second pusher arm 92b does not collide with the first pusher arm 91b.

Because the first pusher arm 91a and the second pusher arm 92b are provided at different positions in the vertical direction Z, the first pusher arm 91a and the second pusher arm 92b do not collide with each other even when either one moves. The same relationship applies between the first pusher arm 91a and the first pusher arm 91b, between the second pusher arm 92a and the second pusher arm 92b, and between the first pusher arm 91b and the second pusher arm 92a. Therefore, the first pusher arm 91a, the second pusher arm 92a, the first pusher arm 91b, and the second pusher arm 92b are able to move the four pushers forward and backward independently.

Because the first driving mechanism 101a can move in the vertical direction with respect to the second driving mechanism 102a, the configuration will be described. FIG. 10 illustrates the first driving mechanism 101a in a configuration in which each of the blades is positioned as illustrated in FIG. 3. The first driving mechanism 101a moves in the vertical direction Z by following the upper-lower movement of the branched blade 110a. The upper-lower operation of the first driving mechanism 101a is realized by the lifting mechanism 63a.

In the configuration illustrated in FIG. 10, the first driving mechanism 101a pertinent to the uppermost layer is at a position separated from the second driving mechanism 102a in the vertical direction Z. Therefore, there is a large gap between the first driving mechanism 101a and the second driving mechanism 102a. When the branched blade 110a is moved down from the configuration in FIG. 10, the first driving mechanism 101a also moves down while maintaining the positional relationship with the branched blade 110a. At this time, the positions of the branched blade 110a and the first pusher 71a in the vertical direction Z are constant. This is because the first pusher 71a that is connected to the first driving mechanism 101a moves up and down as the first driving mechanism 101a moves up and down.

FIG. 12 illustrates the first driving mechanism 101a after the branched blade 110a has been actually moved down to the position where the first blade piece 121a is located. At this time, the gap between the first driving mechanism 101a and the second driving mechanism 102a is reduced to the minimum.

As illustrated in FIG. 11, because the first pusher arm 91a and the second pusher arm 92a are provided at positions laterally symmetric to each other with respect to the virtual line IL, the first pusher arm 91a and the second pusher arm 92a do not collide with each other even when the first driving mechanism 101a moves down to the vicinity of the second driving mechanism 102a.

The first driving mechanism 101b pertinent to the lowermost layer will now be described. In the configuration illustrated in FIG. 10, the first driving mechanism 101b is at a position separated from the second driving mechanism 102b in the vertical direction Z. Therefore, there is a large gap between the first driving mechanism 101b and the second driving mechanism 102b. When the branched blade 110b is moved up from the configuration in FIG. 10, the first driving mechanism 101b also moves up while maintaining the positional relationship with the branched blade 110b. At this time, the positions of the branched blade 110b and the first pusher 71b in the vertical direction Z are constant. This is because the first pusher 71b that is connected to the first driving mechanism 101b moves up and down as the first driving mechanism 101b moves up and down.

FIG. 12 illustrates the first driving mechanism 101b after the branched blade 110b has been actually moved up to the position where the first blade piece 121b is located. At this time, the gap between the first driving mechanism 101b and the second driving mechanism 102b is reduced to the minimum.

As described above, because the first pusher arm 91b and the second pusher arm 92b are provided at positions laterally symmetric to each other with respect to the virtual line IL, the first pusher arm 91b and the second pusher arm 92b do not collide with each other even when the first driving mechanism 101b moves up to the vicinity of the second driving mechanism 102b.

### 7. Effects of Embodiments

As described above, the first hand 55a according to the embodiment includes the first pusher 71a for gripping a substrate, the first pusher 71a being provided at the proximal end of the branched blade 110a and at a position sandwiched between the pair of first proximal end guides 113a. In addition, the second hand 56a includes the second pusher 72a for gripping a substrate, the second pusher 72a being provided at a position sandwiched between the pair of second proximal end guides 123a. The first pusher 71a includes the first member 711a and the second member 712a, against each of which the substrate comes into abutment, and the third member 721 of the second pusher 72a is provided at a position sandwiched between the first member 711a and the second member 712a. With the configuration, the first pusher 71a and the second pusher 72a are set to positions that are different from each other. Therefore, the pushers 71a, 72a do not interfere with each other even if the first pusher 71a and the second pusher 72a are thickened in the vertical direction. According to the invention, it is possible to provide the substrate transfer apparatus 100 that reliably transfers the substrate W that is warped or thick by holding the substrate W using the thick pushers.

With the configuration according to the embodiment, the second hand 56a is provided at a position not overlapping with the first hand 55a in a plan view. The holder 61a includes the lifting mechanism 63a able to move the first hand 55a and the second hand 56a relatively with respect to each other in the vertical direction, and the lifting mechanism 63a is able to position the first hand 55a and the second hand 56a on the same plane, and to separate the first hand 55a and the second hand 56a are spaced apart from each other in the vertical direction Z. By moving the first hand 55a and the second hand 56a relatively with respect to each other in the vertical direction Z, the configuration according to the embodiment can also be applied to a substrate transfer apparatus capable of changing the number of substrates W to be transferred.

With the configuration according to the embodiment, the first proximal end guides 113a are respectively in a relationship line-symmetric to each other with respect to the virtual line IL halving a substrate W that is circular in a plan view; the first distal end guides 114a are respectively in a relationship line-symmetric to each other with respect to the virtual line IL; the second proximal end guides 123a are respectively in a relationship line-symmetric to each other with respect to the virtual line IL; the second distal end guides 124a are respectively in a relationship line-symmetric to each other with respect to the virtual line IL; the first member 711a and the second member 712a in the first pusher 71a are in a relationship line-symmetric to each other with respect to the virtual line IL, and the second pusher 72a is on the virtual line IL. With the configuration, the first pusher 71a presses the substrate W from the left side and the right side, to press the substrate against the first distal end guides 114a that are in a relationship line-symmetric to each other with respect to the virtual line IL. Furthermore, the second pusher 72a presses the substrate from the center, so that the substrate W is pressed against the pair of second distal end guides 124a that are in a relationship line-symmetric to each other with respect to the virtual line IL. With the configuration, when gripping a viscous substrate, the position of the substrate is not deviated.

The configuration according to the embodiment includes: the first holder 61a having the first hand 55a and the second hand 56a; and the second holder 61b having the first hand 55a and the second hand 56a and provided to be separated from the first holder 61a in the vertical direction. With the configuration, a larger number of substrates can be transferred simultaneously.

With the configuration according to the embodiment, the first hand 55a includes the first driving mechanism 101a able to move the first member 711a and the second member 712a closer to the substrate W while maintaining the relative positions of the first member and the second member, and the second hand 56a includes the second driving mechanism 102a able to move the second pusher 72a closer to the substrate W. With the configuration, by moving the first member 711a and the second member 712a closer to the substrate W synchronously, the first driving mechanism 101a causes the first hand 55a to grip the substrate W. As a result, the substrate W is gripped by receiving the same forces on the left and the right sides thereof, respectively. With the configuration described above, the substrate W can be gripped reliably.

With the configuration according to the embodiment, the first driving mechanism 101a includes: the first power unit 81a that generates power; and the first pusher arm 91a that transmits the power of the first power unit 81a to the first pusher 71a. The second driving mechanism 102a includes: the second power unit 82a that generates power at a position separated from the first power unit 81a in the vertical direction, and the second driving mechanism 102a includes the second pusher arm 92a that transmits the power of the second power unit 82a to the second pusher 72a at a position avoiding the first pusher arm 91a. With the configuration, the substrate transfer apparatus can be configured by stacking the power units in the vertical direction, and the configuration according to the invention can be achieved without a significant change in the design of a conventional apparatus.

### Embodiment 2

The embodiment relates to a substrate processing apparatus 1 on which the substrate transfer apparatus 100 described in Embodiment 1 is mounted. Details thereof will now be described.

### 8. Overall Configuration

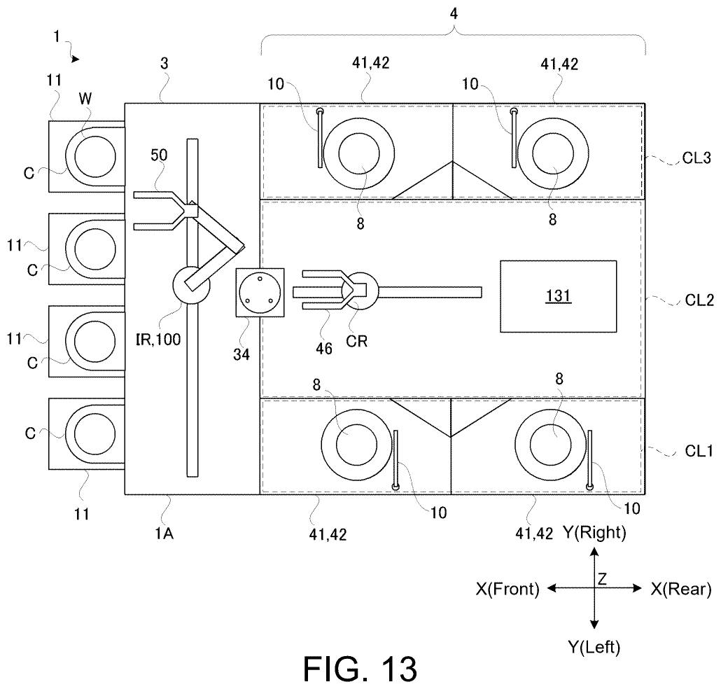

FIG. 13 is a plan view illustrating an overall configuration of the substrate processing apparatus according to the embodiment. The substrate processing apparatus 1 according to the embodiment includes an indexer block 3 and a processing block 4. The substrate processing apparatus 1 includes a block housing 1A that houses the blocks. The block housing 1A has a substantially rectangular shape in a plan view. Loading ports 11 are provided in a manner protruding from a wall surface on an end side of the block housing 1A.

In the embodiment, for the sake of convenience, a direction in which the indexer block 3 and the processing block 4 included in the substrate processing apparatus 1 are aligned will be referred to as a front-rear direction (X direction). The X direction extends horizontally. A direction from the processing block 4 toward the indexer block 3 in the substrate processing apparatus 1 will be referred to as “front”. A direction opposite to the front is referred to as “rear”. A horizontal direction orthogonal to the X direction will be referred to as a left-right direction (Y direction). The Y direction is also a direction in which the loading ports 11 are aligned. One side in the Y direction wills referred to as a right side for the sake of convenience, and the side opposite to the right side will be referred to as a left side. A height direction (Z direction) is orthogonal to both of the X direction and the Y direction, and coincides with the vertical direction. In each of the drawings, front, rear, right, left, top, and bottom are illustrated as appropriate for the reference.

### 9. Indexer Block

As illustrated in FIG. 13, the indexer block 3 includes loading ports 11, each of which is an entrance via which a carrier C storing multiple horizontally oriented substrates W at predetermined intervals in the Z direction is carried into the block. The carrier C can be placed at the loading port 11.

Multiple (e.g., twenty-five) substrates W are stacked and stored inside one carrier C. The carrier C storing therein an unprocessed substrates W to be carried into the substrate processing apparatus 1 is first placed on the loading port 11.

In the indexer block 3, an indexer robot IR capable of simultaneously transferring four horizontally oriented substrates W is disposed. The indexer robot IR may be implemented by using the substrate transfer apparatus 100. The indexer robot IR can access a pass box 34 provided at the boundary between the indexer block 3 and the processing block 4, and any of the four loading ports 11 illustrated in FIG. 1, and is configured to pass the substrate W between the pass box 34 and the carrier C placed on the loading port 11. The indexer robot IR passes the substrate W by using the gripping mechanism 50.

The pass box 34 can support up to four substrates W in a manner stacked in the vertical direction Z.

### 10. Processing Block

The processing block 4 is mainly configured to remove a natural oxide film having grown on the surface of the substrate W. The processing block 4 includes a second line CL2 positioned behind the pass box 34, a first line CL1 provided on the left side of the second line CL2, and a third line CL3 provided on the right side of the second line CL2. The second line CL2 is therefore disposed at a position sandwiched between the first line CL1 and the third line CL3 that are on the left and right sides.

The first line CL1 includes chemical liquid processing chambers 41 aligned in the X direction. The chemical liquid processing chamber 41 includes: a mechanical chuck 8 configured to rotatably support the substrate W; and a nozzle 10 configured to supply chemical liquid onto the substrate W, and the substrate W is processed with the chemical liquid. The chemical liquid processing chamber 41 has a rectangular parallelepiped housing 42 in which the mechanical chuck 8 and the nozzle 10 are housed. In FIG. 13, the first line CL1 is illustrated as having a configuration in which two chemical liquid processing chambers 41 are aligned in the front-rear direction. The first line CL1 includes a stack of chemical liquid processing chambers 41. The stack includes stacking of two or more chemical liquid processing chambers 41.

The second line CL2 provides a passage for a center robot CR transferring horizontally oriented substrates W move forward and backward. The center robot CR can access not only the pass box 34 described above but also the chemical liquid processing chambers 41 included in the first line CL1 and the chemical liquid processing chambers 41 included in the third line CL3, which will be described later.

The center robot CR is able to move forward and backward freely in the X direction, and able to move upward and downward freely in the Z direction so that the center robot CR can transfer the substrate W to each of the accessible positions. The center robot CR can also direct the hand 46 holding the substrate W to any one of the front side, the left side, and the right side.

The third line CL3 has a configuration that is the same as the first line CL1. The third line CL3 has a configuration in which two chemical liquid processing chambers 41 are aligned in the X direction. The third line CL3 includes a stack of chemical liquid processing chambers 41. The stack is configured by stacking of two or more chemical liquid processing chambers 41.

### 11. Other Configurations

As illustrated in FIG. 13, the substrate processing apparatus 1 includes a control unit 131 involved in the control of the apparatus. The control unit 131 is provided with a storage unit, not illustrated in FIG. 13, corresponding thereto. The control unit 131 is implemented as a central processing unit (CPU), for example. The specific configuration of the control unit is not particularly limited. For example, the respective types of control related to the substrate processing apparatus 1 may be implemented by a single processor, or each type of such control may be implemented by an individual processor.

Examples of the control related to the control unit 131 include control related to the indexer robot IR and the center robot CR.

The storage unit stores therein a program, a parameter, and the like related to the control. The storage unit may be implemented as a single device, or may be implemented as individual devices corresponding to respective types of control. Furthermore, the substrate processing apparatus 1 according to the embodiment is not limited by any particular configuration of the device implementing the storage unit.

As described above, the substrate transfer apparatus 100 according to the embodiment can be used in the substrate processing apparatus 1.

### 12. Modified Examples

The invention is not limited to the configurations described above, and modified examples such as those described below, are still possible.

### Modified Example 1

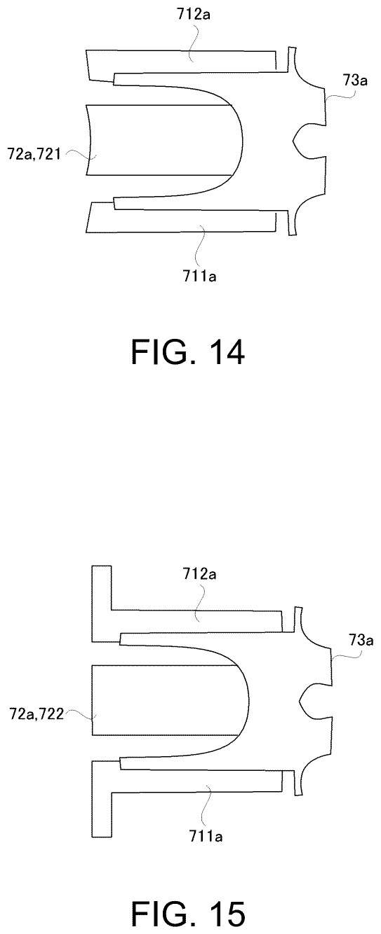

In the modified example illustrated in FIG. 14, each of the distal ends of the first member 711a and the second member 712a of the first pusher 71a with which the substrate W comes into abutment has a shape conforming to the shape of the substrate W, and the distal end of the second pusher 72a against which the substrate comes into abutment also has a shape conforming to the shape of the substrate W. With the configuration, the first member 711a and the second member 712a of the first pusher 71a can grip the substrate W by using a wider contact surface. Therefore, the substrate W is gripped by the first pusher 71a more reliably. In the same manner, the distal end of the second pusher 72a can grip the substrate W with a wider contact surface. Therefore, the substrate W is also gripped more reliably by the second pusher 72a.

### Modified Example 2

In the modified example illustrated in FIG. 15, the distal end of the first member 711a protrudes in a direction orthogonal to the direction in which the first member 711a moves (the direction in which the virtual line IL extends), and the distal end of the second member 712a protrudes in the direction orthogonal to the direction in which the second member 712a moves (the direction in which the virtual line IL extends). With the configuration, the first member 711a and the second member 712a of the first pusher 71a can grip the substrate W by using a wider contact surface. Therefore, the substrate is gripped more reliably by the first pusher 71a.

What is claimed is:

1. A substrate transfer apparatus, transferring a substrate, the substrate transferring apparatus comprising:
a first hand, able to grip a substrate in a horizontal orientation;
a second hand, able to grip a substrate, different from the substrate, in a horizontal orientation;
a holder, aligning the first hand and the second hand in a vertical direction and holding the first hand and the second hand;
an arm, movably supporting the holder; and
a base member, supporting the arm,
wherein the first hand comprises: a first blade; a pair of first proximal end guides, provided at a proximal end of the first blade and supporting the substrate by coming into contact with a bottom surface of the substrate; a pair of first distal end guides, provided at a distal end of the first blade and supporting the substrate by coming into contact with the bottom surface of the substrate; and a first pusher, provided for gripping the substrate, disposed at the proximal end of the first blade, and at a position sandwiched between the pair of first proximal end guides,
the second hand comprises: a second blade; a pair of second proximal end guides, provided at a proximal end of the second blade and supporting the substrate by coming into contact with a bottom surface of the substrate; a pair of second distal end guides, provided at a distal end of the second blade and supporting the substrate by coming into contact with the bottom surface of the substrate; and a second pusher, provided for gripping the substrate, disposed at the proximal end of the second blade, at a position sandwiched between the pair of second proximal end guides, and
the first pusher comprises a first member and a second member, each of the first member and the second member pressing the substrate forward by coming into abutment against the substrate, the second pusher comprises a third member that presses the substrate forward by coming into abutment against the substrate, and the third member is at a position sandwiched between the first member and the second member in a plan view.

2. The substrate transfer apparatus as claimed in claim 1,
wherein the second hand is provided at a position not overlapping with the first hand in a plan view,
the holder comprises a lifting mechanism able to move the first hand and the second hand relatively to each other in the vertical direction, and
the lifting mechanism is able to bring the first hand and the second hand to an in-flush state in which the first hand and the second hand are positioned on a same plane and to a separated state in which the first hand and the second hand are separated in the vertical direction.

3. The substrate transfer apparatus as claimed in claim 1,
wherein the pair of first proximal end guides are respectively in a relationship line-symmetric to each other with respect to a virtual line halving a substrate that is circular in a plan view,
the pair of first distal end guides are respectively in a relationship line-symmetric to each other with respect to the virtual line,
the pair of second proximal end guides are respectively in a relationship line-symmetric to each other with respect to the virtual line,
the pair of second distal end guides are respectively in a relationship line-symmetric to each other with respect to the virtual line,
the first member and the second member in the first pusher are in a relationship line-symmetric to each other with respect to the virtual line, and
the third member of the second pusher is on the virtual line.

4. The substrate transfer apparatus as claimed in claim 1,
wherein distal ends in the first member and the second member of the first pusher that come into abutment against a substrate have a shape conforming to a shape of the substrate, and
a distal end in the third member of the second pusher that comes into abutment against the substrate has a shape conforming to the shape of the substrate.

5. The substrate transfer apparatus as claimed in claim 4,
wherein the distal end of the first member protrudes in a direction orthogonal to a direction in which the first member moves, and
the distal end of the second member protrudes in a direction orthogonal to a direction in which the second member moves.

6. The substrate transfer apparatus as claimed in claim 1, comprising:
a first holder, having the first hand and the second hand; and
a second holder, having two hands similar to the first hand and the second hand, and provided to be separated from the first holder in the vertical direction.

7. The substrate transfer apparatus as claimed in claim 1,
wherein the first hand comprises a first driving mechanism able to move the first member and the second member forward and backward with respect to the substrate while maintaining relative positions of the first member and the second member, and
the second hand comprises a second driving mechanism able to move the third member forward and backward with respect to the substrate.

8. The substrate transfer apparatus as claimed in claim 7,
wherein the first driving mechanism comprises: a first power unit, generating power; and a first pusher arm, transmitting the power of the first power unit to the first member and the second member of the first pusher,
the second driving mechanism comprises a second power unit that generates power at a position separated from the first power unit in the vertical direction, and
the second driving mechanism comprises a second pusher arm that transmits the power of the second power unit to the third member of the second pusher at a position avoiding the first pusher arm.

9. A substrate processing apparatus, comprising the substrate transfer apparatus as claimed in claim 1,
wherein the substrate processing apparatus comprises a single wafer processing chamber that performs a predetermined process on the substrate.
